(19) United States
(12) Patent Application Publication
(10) Pub. No.: US 2015/0162918 A1
(43) Pub. Date: Jun. 11, 2015

(54) DIGITAL OUTPUT CLOCK GENERATION

(71) Applicant: ARM Limited, Cambridge (GB)

(72) Inventor: Ramnath Bommu Subbiah SWAMY, Sheffield (GB)

(73) Assignee: ARM Limited, Cambridge (GB)

(21) Appl. No.: 14/097,963

(22) Filed: Dec. 5, 2013

(51) Int. Cl. H03L 7/081; H03L 7/083

(52) U.S. Cl. CPC H03L 7/081; H03L 7/083

(57) ABSTRACT

An on-chip clock signal generation apparatus is provided which is configured to generate an output clock signal to be passed off-chip in association with an output data signal. The apparatus comprises: an input configured to receive an input clock signal and clock phase generation circuitry configured to generate a plurality of candidate clock signals in dependence on the input clock signal. The candidate clock signals are phase-shifted with respect to one another. Selection circuitry is configured to select and output one of the candidate clock signals as the output clock signal in dependence on at least one selection signal. All components of the apparatus are embodied as digital components.

### BACKGROUND OF THE INVENTION

1. Field of the Invention

The present invention relates to integrated circuit technology. More particularly, this invention relates to on-chip clock signal generation.

2. Description of the Prior Art

It is known to provide a peripheral interface on an integrated circuit implemented as a silicon chip. This interface can be used to export data from the integrated circuit on-chip and such data signals will typically be accompanied by a clock signal also generated on-chip which has a specific relationship with the data signal, in particular indicating the points at which the data signal should be sampled. It is further known that the phase relationship between the data signal and its associated clock signal which are exported off-chip is critical if the data signal is to be correctly sampled.

If it is discovered during the development of an on-chip integrated circuit that the output clock signal and the data signal are not well aligned, then one known approach is to add one or more delay elements to either a data path or a clock path in order to bring about an improved alignment. However, given that such delay elements will then typically be introduced at a relatively late stage in the development process, it can be very difficult or even impossible to introduce such delay elements depending on the layout constraints of the application board. Contemporary highly densely integrated circuit boards further exacerbate these difficulties.

Extremely precise alignment between a clock signal and a data signal is known to be required in very high speed chip interfaces such as those provided as a DDR interface, and in this situation it is known to provide a complex chip interface which is configured to dynamically align the clock and data signal. However the complexity and area overhead associated with such complex interfaces are justifiable only for very high performance interfaces like DDR. For simpler and slower interfaces there is a need for a solution that is easy to implement and verify.

The manual “High Speed Serial I/O Made Simple” by Abhijit Athavale and Carl Christensen of Xilinx, Inc., published in April 2005 provides some background technical information.

It would be desirable to provide an improved technique for allowing an output clock signal and an output data signal to be aligned with one another.

### SUMMARY OF THE INVENTION

Viewed from a first aspect, the present techniques provide an on-chip clock signal generation apparatus configured to generate an output clock signal to be passed off-chip in association with an output data signal, the apparatus comprising:

an input configured to receive an input clock signal;

clock phase generation circuitry configured to generate a plurality of candidate clock signals in dependence on the input clock signal, wherein the candidate clock signals are phase-shifted with respect to one another; and

selection circuitry configured to select and output one of the candidate clock signals as the output clock signal in dependence on at least one selection signal,

wherein all components of the apparatus are embodied as digital components.

The present techniques recognise the significant advantage associated with a portion of an on-chip system being solely embodied by digital components. Mixed digital/analogue circuitry can result in a longer and more expensive implementation process, due to the need to involve a greater range of expertise in the process. A system component which is solely embodied by digital elements can however be easily implemented using standard digital implementation techniques, i.e. both with regard to the selection of and placement of the digital components in the layout stage and in the subsequent static timing analysis stage.

Further, the present techniques recognise the advantage associated with not having to vary the layout of the integrated circuit late in the implementation process. To this end, clock phase generation circuitry is provided which is configured to generate multiple candidate clock signals, where these candidate clock signals are phase-shifted with respect to one another. Accordingly, the effect is that a range of clock signal timings are available and accordingly the output data signal can be sampled at different points, depending on which candidate clock signal is used. Selection circuitry is further provided to select one of these candidate clock signals to be passed off-chip as the output clock signal in association with the output data signal. This selection is performed on the basis of at least one selection signal, this selection signal therefore giving the system implementer the flexibility to vary the timing of the output clock signal by selecting a different candidate clock signal to use. Accordingly, the need to align the output clock signal and data signal on the application board as part of the design process is greatly reduced, or even eliminated, because of the possibility of adjusting the timing of the output clock even in manufactured silicon. Furthermore, the on-chip clock signal generation apparatus can be simply implemented in the same manner as any other digital logic using standard cells, and can be placed and routed using standard digital layout tools. Avoiding analogue design in the circuitry reduces the design and implementation costs. As such, the bring-up time and bill of material (BOM) of the system board can be reduced and the need for late-stage adjustment of a contemporary densely integrated board, usually associated with considerable difficulty, is avoided.

The input clock signal may be at the same frequency as the output signal, or may differ therefrom in dependence on the particular configuration of the clock phase generation circuitry. In particular, in one embodiment, the input clock signal has twice the frequency of the output clock signal.

A configuration in which the input clock signal has twice the frequency of the output clock signal may for example be used in an embodiment wherein the clock phase generation circuitry comprises a frequency divider configured to receive the input clock signal and to generate an intermediate clock signal which has the frequency of the output clock signal, and an inverter configured to invert the input clock signal before the frequency divider. This then, for example by triggering on the leading edge of the clock signal, enables the generation of a 90° phase shifted version of the output clock signal.

The frequency divider could be provided in a number of ways, but in one embodiment the frequency divider comprises a flip-flop, wherein a data output of the flip-flop is coupled to a data input of the flip-flop. A flip-flop represents a commonly used digital component which may therefore be easily implemented within the context of the digital implementation required for the present techniques.

In some embodiments the clock phase generation circuitry comprises at least one inverter, the at least one inverter configured to generate a substantially 180° phase shift between at least two of the candidate clock signals.

In some embodiments the clock phase generation circuitry comprises at least one buffer, the at least one buffer configured to generate a smallest phase shift which is present between any two of the candidate clock signals. Accordingly, by appropriate provision of this at least one buffer the smallest phase shift generated between any two of the candidate clock signals can be provided. This may comprise a single suitably sized buffer or may comprise several concatenated buffers.

The smallest phase shift may be freely set by the system designer, but in some embodiments the smallest phase shift is a substantially 90° phase shift.

The selection circuitry may be provided in a variety of configurations, but in some embodiments the selection circuitry comprises at least one multiplexer, wherein the at least one multiplexer is configured to take the candidate clock signals as its inputs and to provide the output clock signal as its output in dependence on the at least one selection signal.

The at least one selection signal may be provided in a variety of ways. For example, in one embodiment the apparatus further comprises at least one static register configured to provide the at least one selection signal. Thus, a register may be on-chip and programmable according to known techniques, to set up the at least one selection signal. Alternatively in another embodiment the apparatus further comprises at least one primary chip input configured to receive at least one selection signal from off-chip. This provided the system implementer with a direct access from off-chip to control the configuration of the at least one selection signal, facilitating the alignment of the output clock signal and the data signal.

Viewed from a second aspect the present invention provides a computer-readable storage medium storing a data structure comprising at least one standard cell circuit definition for controlling a computer to generate and validate a circuit layout of an integrated circuit, said integrated circuit comprising the apparatus according to the first aspect.

Viewed from a third aspect the present invention provides an on-chip clock signal generation apparatus configured to generate an output clock signal to be passed off-chip in association with an output data signal, the apparatus comprising:

means for receiving an input clock signal;

means for generating a plurality of candidate clock signals in dependence on the input clock signal, wherein the candidate clock signals are phase-shifted with respect to one another; and

means for selecting and outputting one of the candidate clock signals as the output clock signal in dependence on at least one selection signal,

Viewed from a fourth aspect the present invention provides a method of generating an output clock signal to be passed off-chip in association with an output data signal, the method comprising the steps of:

receiving an input clock signal;

generating a plurality of candidate clock signals in dependence on the input clock signal, wherein the candidate clock signals are phase-shifted with respect to one another; and

selecting and outputting one of the candidate clock signals as the output clock signal in dependence on at least one selection signal,

wherein all steps of the method are performed using digital components.

In one embodiment, the method further comprises the steps of receiving the output clock signal and the output data signal off-chip;

determining a phase relationship between the output clock signal and the output data signal; and

adjusting the phase relationship by changing the at least one selection signal. Accordingly, the user has the ability to adjust the phase relationship between the output clock signal and the output data signal by means of altering the selection signal(s).

In one embodiment, the phase relationship between the output clock signal and the output data signal determines a phase point at which the output data signal is sampled. It is typically the timing of the sampling of the output data signal using, for example, a rising edge of the output clock signal to indicate the sampling point which is the most critical factor in ensuring that the output data signal is correctly interpreted off-chip.

Whilst the method steps may be carried out as part of the development process, in embodiments the method steps are carried out after silicon implementation of the digital components. Despite the fact that the chip is then in a physically final silicon implemented form, the method nevertheless allows the adjustment of the timing of the clock signal by the use of the at least one selection signal.

Viewed from a fifth aspect the present techniques provide a method of generating and verifying a circuit layout comprising the apparatus of the first aspect, the method being performed using digital implementation techniques. Accordingly, the circuit layout may be particularly easily and efficiently produced by virtue of the fact that standard digital implementation techniques alone are employed, meaning for example that analogue design techniques are avoided which are commonly associated with additional design costs and time.

### BRIEF DESCRIPTION OF THE DRAWINGS

The present invention will be described further, by way of example only, with reference to embodiments thereof as illustrated in the accompanying drawings, in which:

FIG. 1 schematically illustrates an integrated circuit embodied on-chip, comprising a clock signal generation apparatus in one embodiment;

FIG. 2 schematically illustrates the relative timing of a data signal and four candidate clock signals in one embodiment;

FIG. 3 schematically illustrates in more detail the configuration of an output clock signal generator in one embodiment;

FIG. 4 shows a table giving the resulting phase difference between the input clock signal and output clock signal in one embodiment;

FIG. 5 schematically illustrates in more detail the configuration of the output clock signal generator in one embodiment;

FIG. 6 schematically illustrates a sequence of steps which are taken in the method of one embodiment;

FIG. 7 schematically illustrates a sequence of steps which are taken in the method of one embodiment; and

FIG. 8 schematically illustrates a generic computing device on which aspects of the present techniques may be carried out.

### DESCRIPTION OF THE PREFERRED EMBODIMENTS

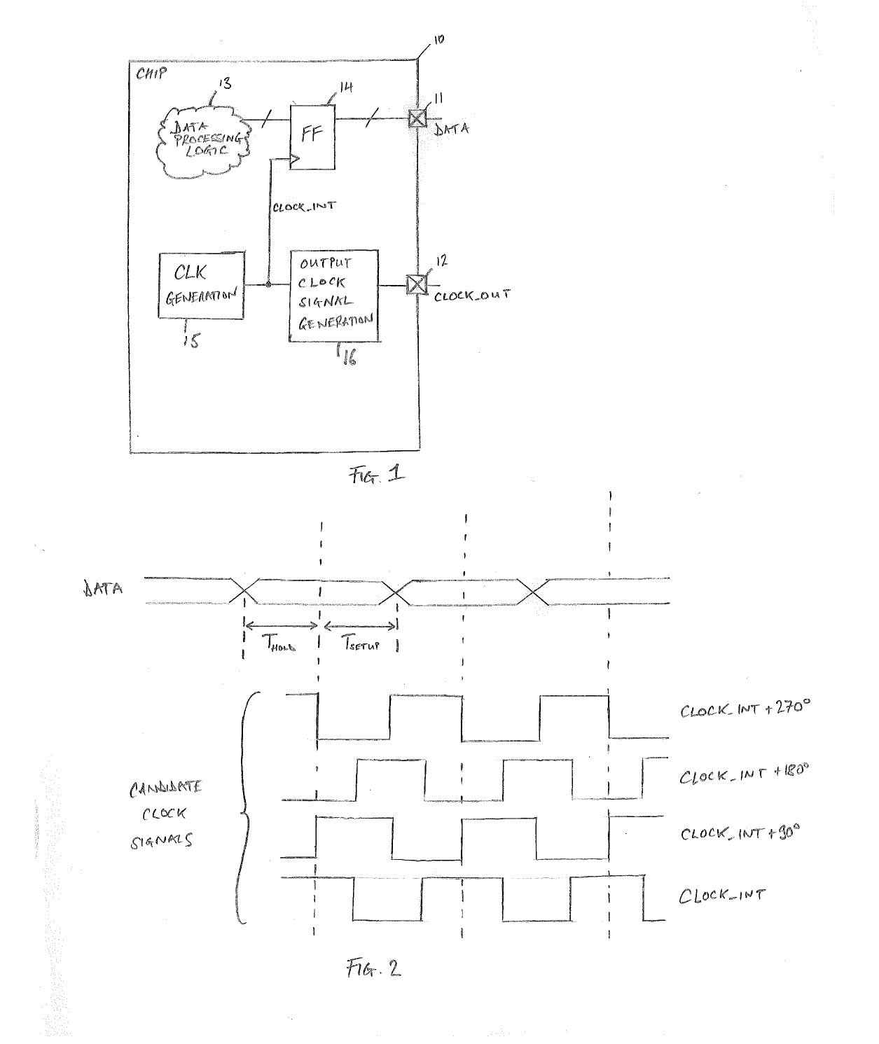

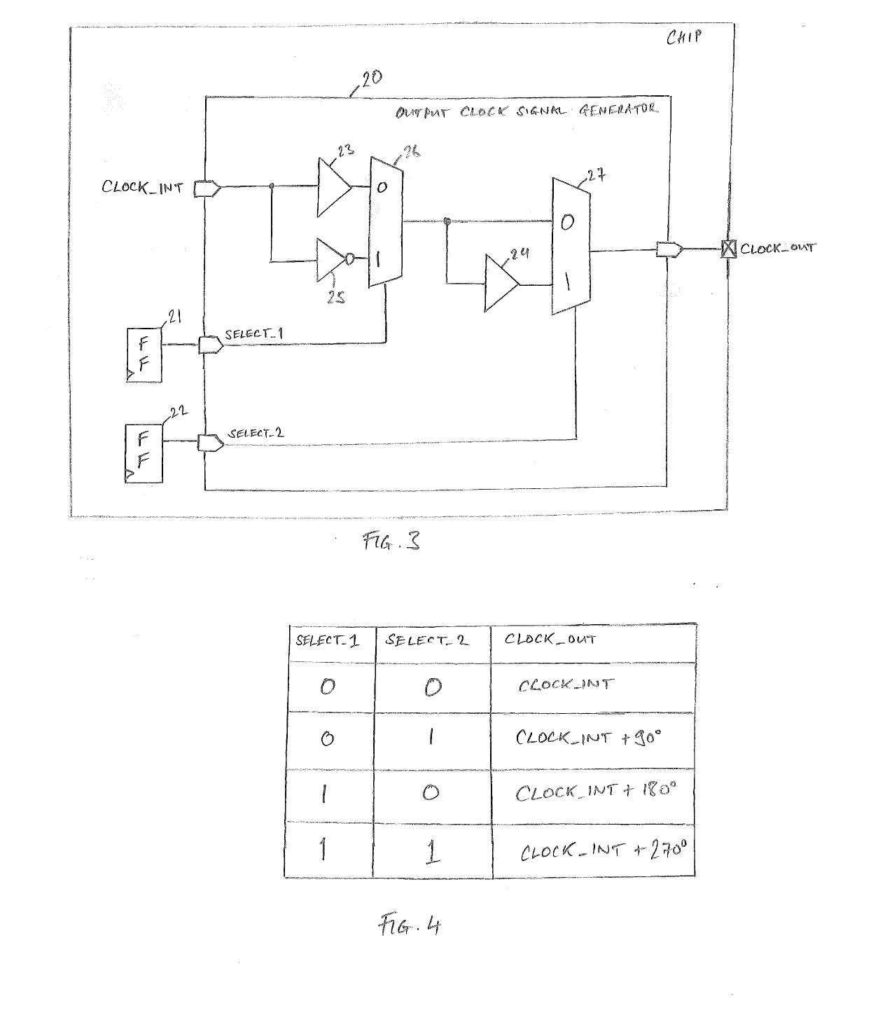

FIG. 1 schematically illustrates an integrated circuit embodied on a silicon chip 10. At the periphery of the chip there are provided a number of output pins, of which only two are illustrated here for clarity. A first pin 11 is provided as a data output path whilst a pin 12 is provided as a clock output path. The output clock signal provided at the pin 12 is in particular provided such that the data signal received via output pin 11 can be correctly interpreted, as will be discussed in more detail below with reference to FIG. 2. The integrated circuit generally comprises data processing logic 13 which generates data signals which are required to be exported off-chip. For this purpose the signals are passed via at least one flip-flop 14, coupled to the output pin 11. The timing of the output data signal thus depends on the timing of a clock signal CLOCK_INT which gates the operation of the flip-flop 14. The signal CLOCK_INT is generated by an on-chip clock generation unit 15. The output clock signal CLOCK_OUT provided at the output pin 12 is generated in dependence on the on-chip signal CLOCK_INT, by the output clock signal generation unit 16. The output clock signal generation unit 16 forms an entirely digital sub-component of the integrated circuit embodied on the chip 10 and therefore at least this part of the integrated circuit can be generated using standard digital implementation techniques for placing the sub-components of this output clock signal generation unit 16 and to verify its operation (for example using static timing analysis (STA)). The output clock signal generation unit 16 is in particular configured to be able to generate the output clock signal CLOCK_OUT at a range of different phases with respect to the output DATA signal. The benefit of being able to do this is now described with reference to FIG. 2.

FIG. 2 schematically illustrates the relative timing of the DATA signal and a range of candidate clock signals which are internally generated by the output clock signal generation unit 16 shown in FIG. 1. As can be seen from the Figure, the candidate clock signals are each phase-offset with respect to one another by 90°. Considering in particular the clock signal illustrated lowermost in FIG. 2, this clock signal corresponds directly to the input clock signal CLOCK_INT received by the output clock signal generation unit 16, i.e. without any additional phase shift. However, comparing the timing of this clock signal to the timing of the DATA signal uppermost in FIG. 2, it can be seen that if the data signal is sampled at points corresponding to the rising edge of this clock signal then the data signal will be sampled at a rather offset position, in particular where the setup and hold times T_{SETUP} and T_{HoLD} are rather imbalanced. Whilst for particular implementation reasons it may not be required for the setup and hold times to be identical to one another, it will generally result in a more reliable interpretation of the data signal if the point at which the data signal is sampled lies approximately centrally in the data eye. Accordingly, considering the range of candidate clock signals generated by the output clock signal generation unit 16 shown in FIG. 2, it can be seen that it would be preferable for the DATA signal to be sampled at points indicated by the rising edge of the candidate clock signal CLOCK_INT+90°. The user of the chip 10 is able to configure the output clock signal CLOCK_OUT generated at the output pin 12 to correspond to this selected phase shift by appropriate setting of two selection signals as will be described in more detail below with respect to specific embodiments.

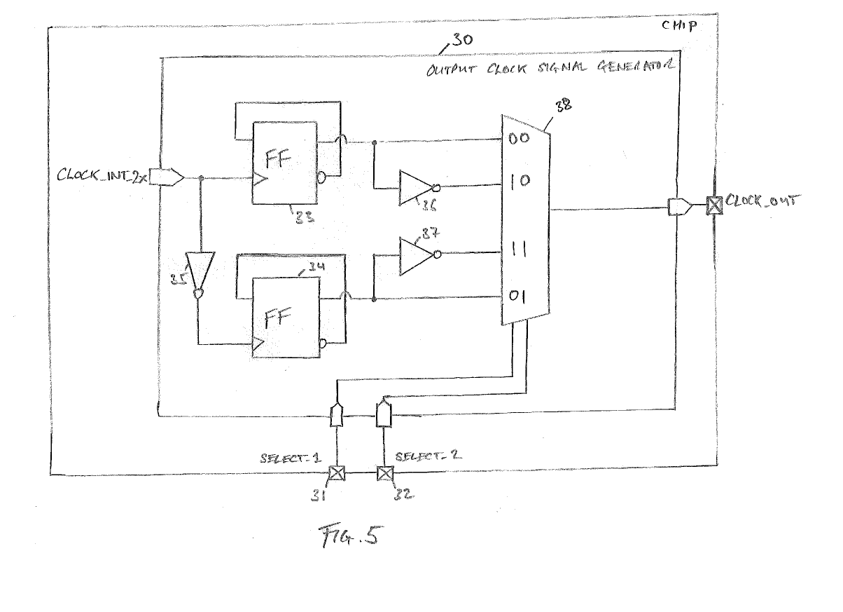

FIG. 3 schematically illustrates in more detail the configuration of an output clock signal generator in one embodiment. In this embodiment, the output clock signal generator 20 is configured to receive two selection signals, SELECT_{—}1 and SELECT_{—}2. These selection signals are respectively received from two static registers 21 and 22 provided on-chip. Accordingly, by configuring the value stored in each of the static registers 21, 22, the system user can configure the operation of the output clock signal generator and most particularly determine the phase relationship between the generated output clock signal CLOCK_OUT and the received input clock signal CLOCK_INT. The clock phase generation circuitry of the output clock signal generator 20 comprises buffers (repeaters) 23, 24 and inverter 25. Buffer 23 and inverter 25 are configured to have similar propagation delays, whilst buffer 24 is configured to have propagation delay which is equal to a quarter of the time period of the input clock signal CLOCK_INT. Thus, in a physical implementation, buffer 24 may in fact be provided by a chain of buffers in order to achieve this desired propagation delay. The output clock signal generator 20 further comprises two multiplexers 26, 27, which are switched in dependence on the selection signals SELECT_{—}1 and SELECT_{—}2. FIG. 4 sets out a table showing the relationship in phase between the output clock signal CLOCK_OUT and the input clock signal CLOCK_INT in dependence on the particular setting of the two selection signals SELECT_{—}1 and SELECT_{—}2. Hence, four different candidate clock signals each with a 90° phase shift with respect to one another are generated within the output clock signal generator 20 and appropriate setting of the selection signals SELECT_{—}1 and SELECT_{—}2 determines which is provided as the output clock signal CLOCK_OUT.

The faster the clock frequency used for the output clock signal generator 20, the smaller the propagation delay provided by buffer 24 needs to be. As such, this embodiment is more suitable for high frequencies of CLOCK_INT, e.g. 400 MHz or above, since fine granularity in the phase shift generated by the buffer 24 can be achieved by using a fast buffer for this component.

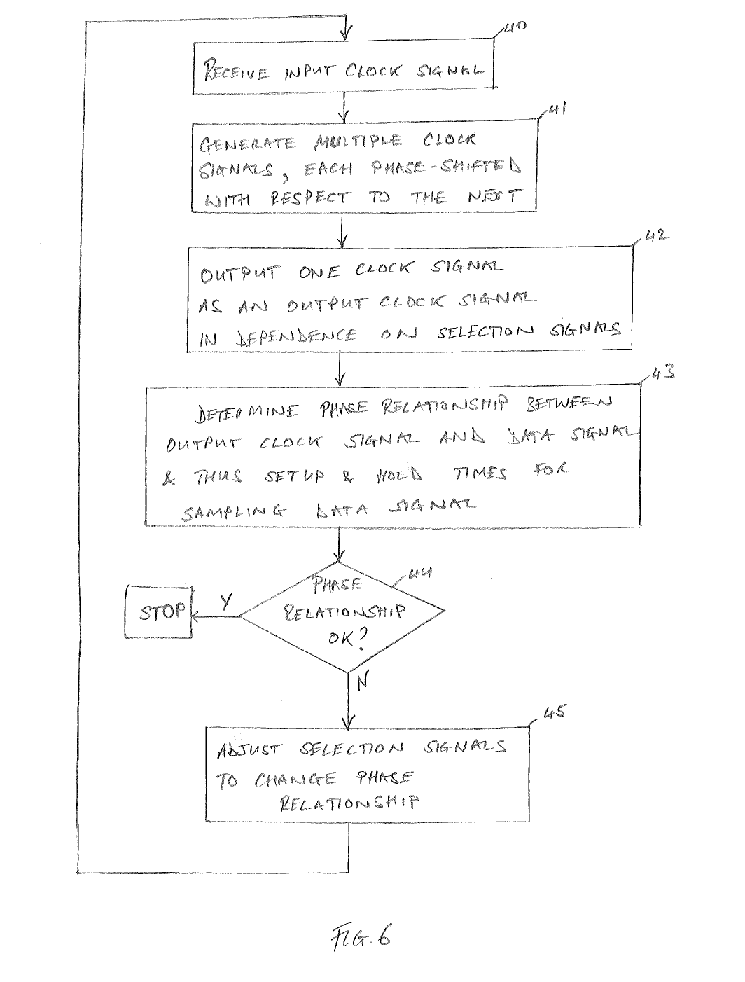

FIG. 5 schematically illustrates a different configuration of the output clock signal generator. In this embodiment, the output clock signal generator 30 is configured to select the candidate clock signal to output as the output clock signal CLOCK_OUT in dependence on selection signals SELECT_{—}1 and SELECT_{—}2 which are received at dedicated pins 31, 32 on the periphery of the chip. It should be noted that this choice of configuration for the provision of the selection signals SELECT_{—}1 and SELECT_{—}2 does not have any particular association with the configuration within output clock signal generator 30 and could also be used to provide the selection signals for the output clock signal generator 20 shown in FIG. 3. Conversely the selection signals SELECT_{—}1 and SELECT_{—}2 in FIG. 5 could equally be provided by on-chip static registers such as those shown in FIG. 3.

A particular feature of the output clock signal generator 30 is that it is configured to receive an input clock signal CLOCK_INT_{—}2× which has double the clock frequency which is required for the output clock signal CLOCK_OUT. The clock phase generation circuitry in output clock signal generator 30 comprises two flip-flops 33, 34 and three inverters 35, 36 and 37. The flip-flops 33, 34 are self-coupled in that the inverted output of each is fed back to provide the data input of each. This configures the flip-flops 33, 34 to act as frequency dividers, such that for example the output of flip-flop 33 corresponds to the original single-speed clock signal CLOCK_INT, which can therefore be output as a non-phase-shifted clock signal at the output CLOCK_OUT. The provision of the inverter 35 on the input of the clock input of flip-flop 34 results in a 90° phase shift in the output of flip-flop 34 with respect to the output of flip-flop 33, by virtue of the fact that flip-flop 33 and 34 are rising-edge triggered flip-flops and the inversion of the double frequency clock signal CLOCK_INT_{—}2× thus shifts the rising edge by 90° with respect to the single-frequency clock signal CLOCK_INT. Inverters 36 and 37 provide 180° phase shifts with respect to the output of each flip-flop 33, 34 respectively. Accordingly, a set of four candidate clock signals each phase shifted by 90° with respect to the next are generated by the output clock signal generator 30. The output clock signal generator 30 further comprises a multiplexer 38 which is configured to provide one of these candidate clock signals as the output clock signal CLOCK_OUT in dependence on the configuration of the selection signals SELECT_{—}1 and SELECT_{—}2. The specific relationship between the selection signals and the phase shift of the output clock signal CLOCK_OUT is the same as that shown in the table of FIG. 4.

Whilst the output clock signal generator 20 shown in FIG. 3 was described as being more suitable at higher clock frequencies, the output clock signal generator 30 shown in FIG. 5 is more suitable at lower clock frequencies (e.g. at 400 MHz and below). In particular, this is due to the fact that unlike in the output clock signal generator 20, in output clock signal generator 30 there is no need to add a buffer providing a quarter clock period delay to the clock path, which at lower frequencies could be a considerable delay, potentially requiring multiple concatenated buffers in a chain. Process-voltage-temperature (PVT) variation in an implementation based on the embodiment of FIG. 3 could then (at these lower frequencies) result in considerable variation in that total delay due to the number of individual buffers potentially required. Accordingly, at relatively low operating frequencies (by contemporary standards, e.g. at 200 MHz) the embodiment shown in FIG. 5 represents an advantageously reliable output clock signal generator which is only weakly susceptible to PVT variations.

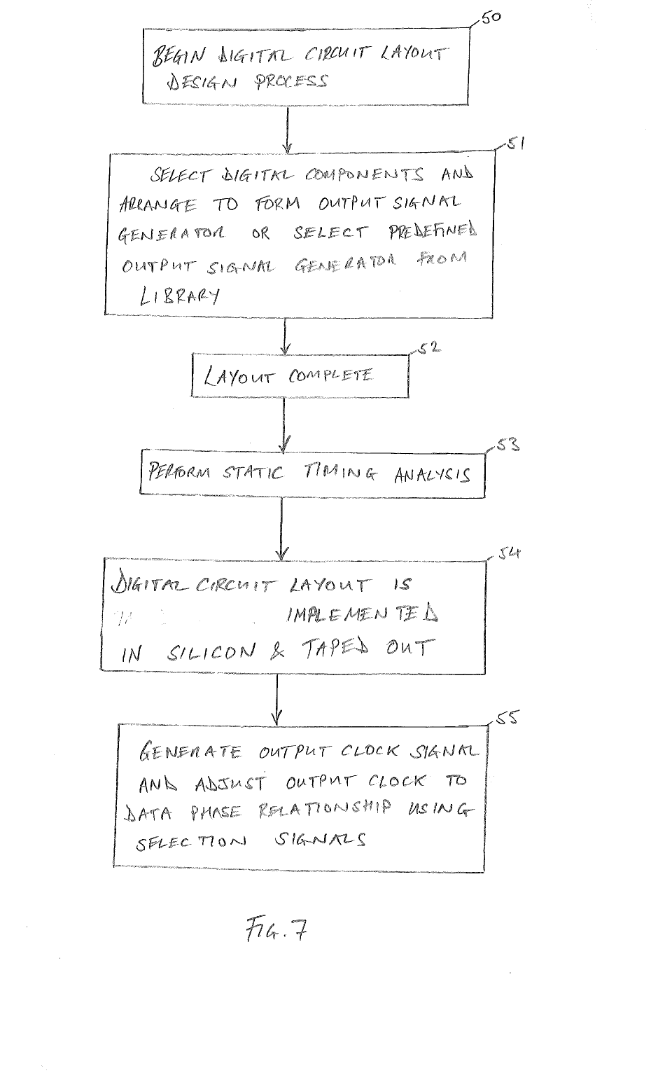

FIG. 6 schematically illustrates a sequence of steps which may be taken by the method of one embodiment. The flow can be considered to begin at step 40 where an input clock signal is received. Next, at step 41, multiple clock signals are generated in dependence on that input clock signal, wherein each is phase-shifted with respect to the next. Then at step 42 one of the clock signals is output as an output clock signal which is passed off-chip in association with an output data signal, the choice of which of the multiple clock signals to choose being made in dependence on the current configuration of the selection signals. Then, at step 43, the phase relationship between the output clock signal and the data signal is determined, in particular, the phase relationship between the rising edge of the output clock signal and the ideal sampling point of the data signal is compared (i.e. the set up and hold times for sampling the data signal are determined). At step 44 it is then determined whether this phase relationship is acceptable or not. If it is then the flow can then simply stop, and the chip can be allowed to function as it is currently configured. If however this phase relationship could be improved, i.e. because one of the other generated clock signals, at a different phase shift, would provide a better sampling point for the data signal, then the flow proceeds via step 45 where the selection signals are adjusted to change which of the generated clock signals is output as the output clock signal and the flow then returns to step 40.

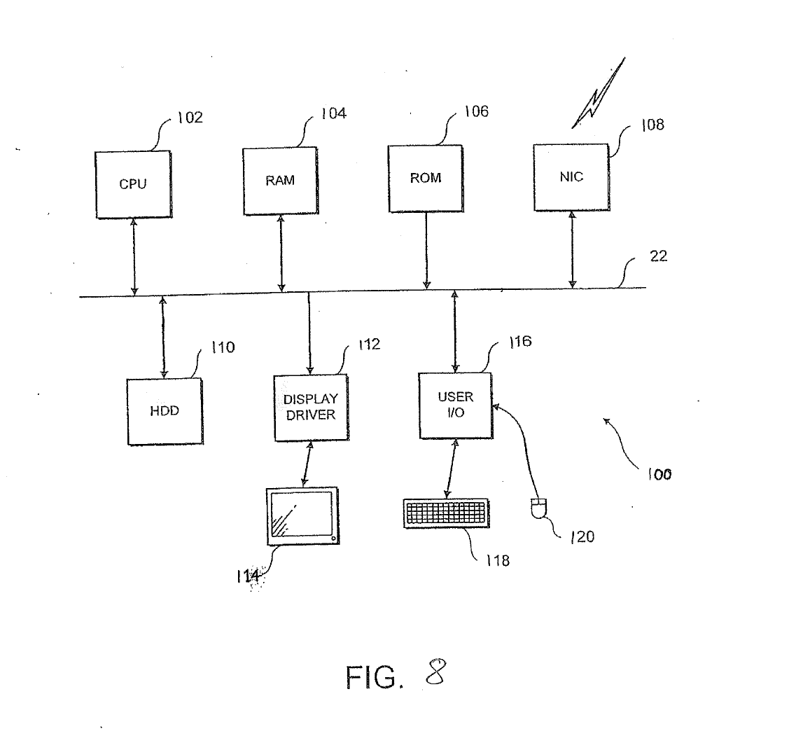

FIG. 7 schematically illustrates a sequence of steps which are taken in a method of one embodiment in which a chip on which an output clock signal generation unit according to the present techniques is implemented is designed, tested, manufactured and then used. The flow begins at step 50 where the digital circuit layout design process begins. Given that this is a purely digital design process, the process of performing the layout of the digital circuit, carried out at step 51, is performed using standard digital implementation techniques. For example, digital components may be selected from a library of such digital components and arranged together to provide the output signal generator, or indeed an output signal generator itself may form a predefined component which maybe selected from that library. It will be understood that the full layout of an integrated circuit comprising many different components beyond the output signal generator will involve considerable further design process, but ultimately the layout is complete at step 52. Then at step 53 the digital components may be subject to a static timing analysis (STA) in order to verify that the timing requirements for the digital circuit are met. It will be further understood that this STA work at step 53 may well be an iterative process, in particular where an alteration of the layout is required in order to meet the timing requirements. However, once this is complete then at step 54 the digital circuit layout can be implemented in silicon and taped out. Finally, at step 55 the manufactured silicon chip can be used to generate an output clock signal and the phase relationship between the output clock signal and the data signal can be adjusted using appropriate configuration of the selection signals.

FIG. 8 schematically illustrates a general purpose computing device 100 of the type that may be used to implement some of the above described techniques. The general purpose computing device 100 includes a central processing unit 102, a random access memory 104 and a read only memory 106, connected together via bus 122. It also further comprises a network interface card 108, a hard disk drive 110, a display driver 112 and monitor 114 and a user input/output circuit 116 with a keyboard 118 and mouse 120 all connected via the common bus 122. In operation, such as when executing data processing instructions which include an instruction configured to cause the device to carry out the present techniques, the central processing unit 102 will execute computer program instructions that may for example be stored in the random access memory 104 and/or the read only memory 106. Program instructions could be additionally retrieved from the hard disk drive 110 or dynamically downloaded via the network interface card 108. The results of the processing performed may be displayed to a user via a connected display driver 112 and monitor 114. User inputs for controlling the operation of the general purpose computing device 100 may be received via a connected user input output circuit 116 from the keyboard 118 or the mouse 120. It will be appreciated that the computer program could be written in a variety of different computer languages. The computer program may be stored locally on a recording medium or dynamically downloaded to the general purpose computing device 100. When operating under control of an appropriate computer program, the general purpose computing device 100 can be used to design and verify the layout of an integrated circuit for implementation on-chip. For example a library of digital components which may be used in that layout may be stored in the random access memory 104 and/or the read only memory 106 and/or the hard disk drive 110 and/or dynamically downloaded via the network interface card 108. The architecture of the general purpose computing device 100 could vary considerably and FIG. 8 is only one example.

Although particular embodiments of the invention have been described herein, it will be apparent that the invention is not limited thereto, and that many modifications and additions may be made within the scope of the invention. For example, various combinations of the features of the following dependent claims could be made with the features of the independent claims without departing from the scope of the present invention.

I claim:

1. An on-chip clock signal generation apparatus configured to generate an output clock signal to be passed off-chip in association with an output data signal, the apparatus comprising:
an input configured to receive an input clock signal;
clock phase generation circuitry configured to generate a plurality of candidate clock signals in dependence on the input clock signal, wherein the candidate clock signals are phase-shifted with respect to one another; and
selection circuitry configured to select and output one of the candidate clock signals as the output clock signal in dependence on at least one selection signal,
wherein all components of the apparatus are embodied as digital components.

2. The apparatus as claimed in claim 1, wherein the input clock signal has twice the frequency of the output clock signal.

3. The apparatus as claimed in claim 2, wherein the clock phase generation circuitry comprises a frequency divider configured to receive the input clock signal and to generate an intermediate clock signal which has the frequency of the output clock signal, and an inverter configured to invert the input clock signal before the frequency divider.

4. The apparatus as claimed in claim 3, wherein the frequency divider comprises a flip-flop, wherein a data output of the flip-flop is coupled to a data input of the flip-flop.

5. The apparatus as claimed in claim 1, wherein the clock phase generation circuitry comprises at least one inverter, the at least one inverter configured to generate a substantially 180° phase shift between at least two of the candidate clock signals.

6. The apparatus as claimed in claim 1, wherein the clock phase generation circuitry comprises at least one buffer, the at least one buffer configured to generate a smallest phase shift which is present between any two of the candidate clock signals.

7. The apparatus as claimed in claim 6, wherein the smallest phase shift is a substantially 90° phase shift.

8. The apparatus as claimed in claim 1, wherein the selection circuitry comprises at least one multiplexer, wherein the at least one multiplexer is configured to take the candidate clock signals as its inputs and to provide the output clock signal as its output in dependence on the at least one selection signal.

9. The apparatus as claimed in claim 1, further comprising at least one static register configured to provide the at least one selection signal.

10. The apparatus as claimed in claim 1, further comprising at least one primary chip input configured to receive the at least one selection signal from off-chip.

11. A computer-readable storage medium storing a data structure comprising at least one standard cell circuit definition for controlling a computer to generate and validate a circuit layout of an integrated circuit, said integrated circuit comprising the apparatus according to claim 1.

12. An on-chip clock signal generation apparatus configured to generate an output clock signal to be passed off-chip in association with an output data signal, the apparatus comprising:
means for receiving an input clock signal;
means for generating a plurality of candidate clock signals in dependence on the input clock signal, wherein the candidate clock signals are phase-shifted with respect to one another; and
means for selecting and outputting one of the candidate clock signals as the output clock signal in dependence on at least one selection signal,
wherein all components of the apparatus are embodied as digital components.

13. A method of generating an output clock signal to be passed off-chip in association with an output data signal, the method comprising the steps of:
receiving an input clock signal;
generating a plurality of candidate clock signals in dependence on the input clock signal, wherein the candidate clock signals are phase-shifted with respect to one another; and
selecting and outputting one of the candidate clock signals as the output clock signal in dependence on at least one selection signal,
wherein all steps of the method are performed using digital components.

14. The method of claim 13, further comprising the steps of:
receiving the output clock signal and the output data signal off-chip;
determining a phase relationship between the output clock signal and the output data signal; and
adjusting the phase relationship by changing the at least one selection signal.

15. The method of claim 14, wherein the phase relationship between the output clock signal and the output data signal determines a phase point at which the output data signal is sampled.

16. The method of claim 13, wherein the method steps are carried out after silicon implementation of the digital components.

17. A method of generating and verifying a circuit layout comprising the apparatus as claimed in claim 1, the method being performed using digital implementation techniques.
